(19) United States
(12) Patent Application Publication
(10) Pub. No.: US 2025/0221237 A1
(43) Pub. Date: Jul. 3, 2025

(54) RELEASE FILM

(71) Applicant: Samsung Display Co., LTD., Yongin-si (KR)

(72) Inventor: JOONHYUK JANG, Yongin-si (KR)

(21) Appl. No.: 18/906,640

(22) Filed: Oct. 4, 2024

(30) Foreign Application Priority Data
Jan. 2, 2024 (KR) 10-2024-0000332

(51) Int. Cl. H10K 59/80; B32B 3/26; B32B 7/02; B32B 7/06

(52) U.S. Cl. CPC H10K 59/80; B32B 3/266; B32B 7/02; B32B 7/06; B32B 2307/748; B32B 2457/20

(57) ABSTRACT

Provided is a release film including a protective film on a rear surface of a display device, in a periphery of a first hole defined in the display device, and a hole film adjacent to the protective film on the rear surface of the display device, and overlapping the first hole. The hole film may include a first hole film on the rear surface of the display device, and a second hole film including a first portion on an upper surface of the protective film and an upper surface of the first hole film, and an adhesive strength between the rear surface of the display device and a lower surface of the first hole film is smaller than an adhesive strength between a lower surface of the first portion and the upper surface of the protective film.

### CROSS-REFERENCE TO RELATED APPLICATIONS

The present application claims priority to and the benefit of Korean Patent Application No. 10-2024-0000332, filed on Jan. 2, 2024, in the Korean Intellectual Property Office, the content of which is herein incorporated by reference.

### BACKGROUND

### 1. Field

Embodiments of the present disclosure herein relate to a release film.

### 2. Description of Related Art

Generally, a display device includes a display module for that displays images, and a support part for supporting the display module. The display module includes a display panel which displays images, a window which is on the display panel and protects the display panel against external scratches and impacts, and a cover layer which is below the display panel and protects the display panel against external impacts. The support part has greater rigidity than the display module and supports the display module. The support part includes a support plate including, for example, a metal.

Recently, a display device including a flexible display module is being developed with the technological development of a display device. In the flexible display module, a support part, which is below a display module folded with respect to a folding axis, has a structure which is folded together with the display module.

### SUMMARY

Embodiments of the present disclosure provide a release film which is easily detachable from a display panel.

An embodiment of the present disclosure provides a release film including: a protective film on a rear surface of a display device and at a periphery of a first hole defined in the display device; and a hole film adjacent to the protective film on the rear surface of the display device, and overlapping the first hole, wherein the hole film includes a first hole film on the rear surface of the display device, and a second hole film including a first portion on an upper surface of the protective film and an upper surface of the first hole film, and an adhesive strength between the rear surface of the display device and a lower surface of the first hole film is smaller than an adhesive strength between a lower surface of the first portion and the upper surface of the protective film.

In an embodiment of the present disclosure, a release film includes: a protective film on a rear surface of a display device and at a periphery of a first hole defined in the display device; and a hole film adjacent to the protective film on the rear surface of the display device, and overlapping the first hole, wherein the hole film includes a first hole film on the rear surface of the display device and a second hole film adhered to the first hole film, an adhesive strength between the rear surface of the display device and a lower surface of the first hole film is 0 gf/in, and a border of the second hole film protrudes further outward than a border of the first hole film and adheres to an upper surface of the protective film.

### BRIEF DESCRIPTION OF THE FIGURES

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a perspective view of an electronic device including a display device protected by a release film according to an embodiment of the present disclosure;

FIG. 2 is a perspective view illustrating a state in which the electronic device illustrated in FIG. 1 is folded;

FIG. 3 is an exploded perspective view of the electronic device illustrated in FIG. 1;

FIG. 4 is a block diagram of the electronic device illustrated in FIG. 3;

FIG. 5 is a schematic cross-sectional view of a display module illustrated in FIG. 3;

FIG. 6 is a cross-sectional view illustrating an example of a display panel illustrated in FIG. 5;

FIG. 7 is a plan view of the display panel illustrated in FIG. 6;

FIG. 8A is a cross-sectional view taken along line I-I′ illustrated in FIG. 7;

FIG. 8B is a cross-sectional view illustrating a state in which a bending region illustrated in FIG. 8A is bent;

FIG. 9 is a plan view illustrating a release film according to an embodiment of the present disclosure;

FIG. 10A is a cross-sectional view taken along line II-II′ illustrated in FIG. 9;

FIG. 10B is a cross-sectional view taken along line III-III′ illustrated in FIG. 9;

FIGS. 11A-11B are views illustrating a hole film being detached from the display device of FIG. 9; and

FIGS. 12A-12B are a plan view and a cross-sectional view, respectively, illustrating a release film according to an embodiment of the present disclosure.

### DETAILED DESCRIPTION

It will be clear to understand a feature and a method of achieving the subject matter of the present disclosure, according to an embodiment of the present disclosure, referring to the embodiments described herein in more detail with respect to the accompanying drawings. However, it is to be understood that the embodiments of the present disclosure disclosed below are not limited, but may be implemented in various suitable forms different from each other. Also, the embodiments are merely provided to provide a complete disclosure of the subject matter of the present disclosure, and to fully inform one skilled in the art of the technical scope of the present disclosure. The technical scope of the present disclosure should be determined by the appended claims and equivalents thereof. Like reference numerals or symbols refer to like elements throughout.

It will be understood that when an element or a layer is referred to as “being on an upper of” or “being on” another element or layer, it includes not only a case of being directly on another element or layer, but also a case where intervening elements are therebetween. On the contrary, when an element is referred to as being “directly on” or “on top”, it means that there are no intervening layers or elements therebetween. The term “and/or” includes all combinations of one or more of the associated listed items.

The spatially relative terms such as “below”, “beneath”, “lower”, “above”, “upper” and the like, may be used herein for ease of description to describe one element or feature's relationship to another element or feature as illustrated in the drawings. It will be understood that the spatially relative terms are intended to encompass different orientations of the device in use or operation in addition to the orientation depicted in the drawings. Like reference numerals or symbols refer to like elements throughout.

It will be understood that, although the terms first, second, etc. may be used herein to describe various elements, components and/or sections, these elements, components and/or sections should not be limited by these terms. These terms are only used to distinguish one element, component, or section from another element, component or section. Thus, a first element, component, or section discussed below could be termed a second element, component, or section without departing from the spirit or scope of the present disclosure.

The embodiments described herein will be explained with reference to the ideal (or schematic) plan, perspective, and cross-sectional views of embodiments of the present disclosure. Accordingly, the shapes of illustrative drawings may be modified according to manufacturing techniques and/or tolerances. Therefore, the embodiments of the present disclosure are not limited to the illustrated specific shapes in the drawings, but also include shape changes caused by, for example, manufacturing processes. Accordingly, the regions illustrated in the drawings may be schematic, and the shapes of the regions illustrated in the drawings that illustrate a specific shape of a region in a device are not intended to limit the scope of the present disclosure.

Hereinafter, example embodiments of the present disclosure will be described in more detail with reference to the attached drawings.

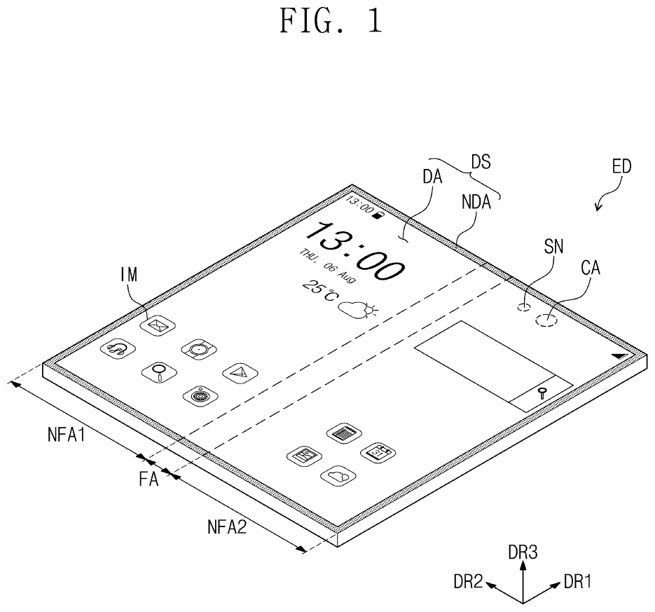

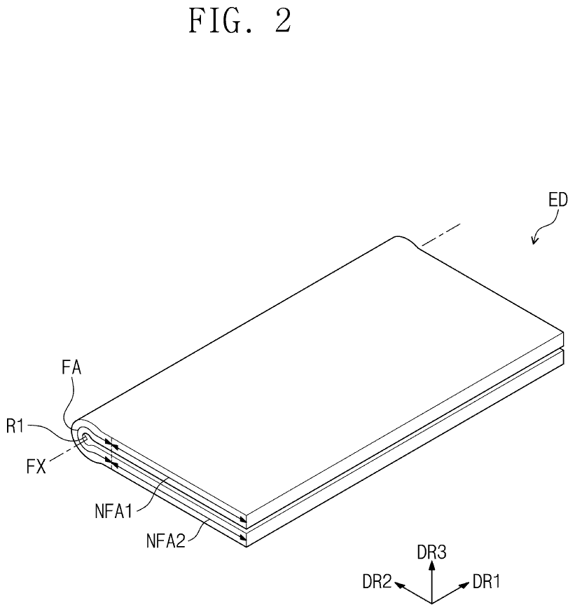

FIG. 1 is a perspective view of an electronic device including a display device protected by a release film according to an embodiment of the present disclosure. FIG. 2 is a perspective view illustrating a state in which the electronic device illustrated in FIG. 1 is folded.

Referring to FIG. 1, an electronic device ED according to an embodiment of the present disclosure may have a rectangular shape which has long sides extending in a first direction DR1 and short sides extending in a second direction DR2 crossing the first direction DR1. However, embodiments of the present disclosure are not limited thereto, and the electronic device ED may have various suitable shapes, such as, for example, a circular (e.g., generally circular) or polygonal shape. The electronic device ED may be a flexible display device.

Hereinafter, a direction, which is substantially perpendicular to a plane defined by the first direction DR1 and the second direction DR2, is defined as a third direction DR3. Also, in this specification, the wording “when viewed on a plane” may be defined as a state when viewed in the third direction DR3.

The electronic device ED may include a folding region FA and a plurality of non-folding regions NFA1 and NFA2. The non-folding regions NFA1 and NFA2 may include a first non-folding region NFA1 and a second non-folding region NFA2. The folding region FA may be between the first non-folding region NFA1 and the second non-folding region NFA2. The folding region FA, the first non-folding region NFA1, and the second non-folding region NFA2 may be provided in the second direction DR2.

One folding region FA and two non-folding regions NFA1 and NFA2 are illustrated as examples, but the number of the folding region FA and the number of the non-folding regions NFA1 and NFA2 are not limited thereto. For example, the electronic device ED may include more than two non-folding regions and a plurality of folding regions provided with the non-folding regions therebetween.

An upper surface of the electronic device ED may be defined as a display surface DS, and the display surface DS may have a flat surface defined by the first direction DR1 and the second direction DR2. Images IM generated from the electronic device ED through the display surface DS may be provided to users.

The display surface DS may include a display region DA and a non-display region NDA around the display region DA. The display region DA may display images, and the non-display region NDA may not display images (or may not be designed to actively display images). The non-display region NDA may surround the display region DA and define a border of the electronic device ED printed in a set or predetermined color.

The electronic device ED may include at least one sensor SN and at least one camera CA. The sensor SN and the camera CA may be adjacent to the border of the electronic device ED. The sensor SN and the camera CA may be in the display region DA adjacent to the non-display region NDA. The sensor SN and the camera CA may be in the second non-folding regions NFA2, but are not limited thereto. The sensor SN and the camera CA may be in the first non-folding regions NFA1. By way of example, the sensor SN and the camera CA are shown in the drawings as dotted lines.

Light may pass through portions, of the electronic device ED, in which the sensor SN and the camera CA are provided and may be provided to the camera CA and the sensor SN. For example, the sensor SN may be a proximity sensor, but a type (or kind) of sensor SN is not limited thereto. The camera CA may capture an external image. The sensor SN and the camera CA may each be provided in plurality.

Referring to FIG. 2, an electronic device ED may be a foldable electronic device ED which is folded or unfolded. For example, the electronic device ED may be folded such that a folding region FA is bent with respect to a folding axis FX parallel to the first direction DR1. The folding axis FX may be defined as a long axis parallel (e.g., substantially parallel) to a long side of the electronic device ED.

When the electronic device ED is folded, the electronic device ED may be in-folded such that the first non-folding regions NFA1 and the second non-folding region NFA2 may face each other and the display surface DS is not exposed to the outside. However, embodiments of the present disclosure are not limited thereto. For example, the electronic device ED may be out-folded with respect to the folding axis FX such that the display surface DS is exposed to the outside.

For example, a distance between the first non-folding region NFA1 and the second non-folding region NFA2 may be smaller than a curvature radius R1. However, the distance between the first non-folding region NFA1 and the second non-folding region NFA2 may be substantially the same as the curvature radius R1.

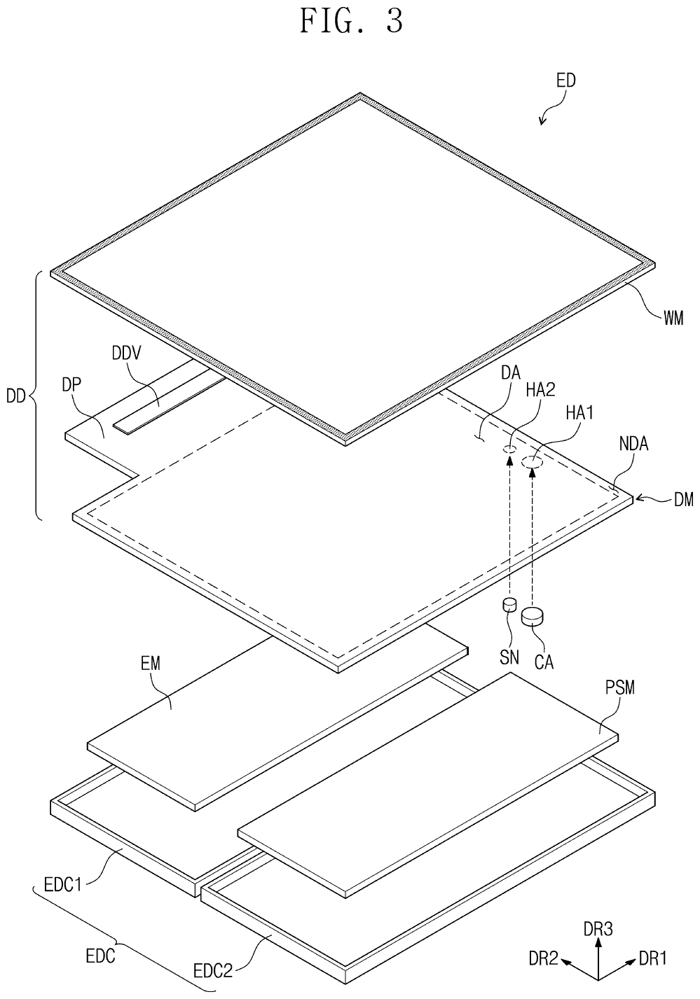

FIG. 3 is an exploded perspective view of the electronic device illustrated in FIG. 1.

Referring to FIG. 3, the electronic device ED may include a display device DD, a camera CA, a sensor SN, an electronic module EM, a power supply module PSM, and a case EDC. In embodiments, the electronic device ED may further include a mechanical structure (for example, hinge) for controlling a folding operation of the display device DD.

The display device DD may generate an image and detect an external input. The display device DD may include a window module WM and a display module DM. The window module WM may provide a front surface of the electronic device ED. The window module WM may be on the display module DM and protect the display module DM. The window module WM may transmit light generated from the display module DM and provide the light to a user.

The display device DD may generate an image and detect an external input. The display device DD may include the window module WM and the display module DM. The window module WM may provide the front surface of the electronic device ED. The window module WM may be on the display module DM and protect the display module DM. The window module WM may transmit light generated from the display module DM and provide the light to a user.

The display module DM may include at least a display panel DP. FIG. 3 illustrates only the display panel DP among stacked structures of the display module DM, but substantially, the display module DM may further include a plurality of components provided above and/or below the display panel DP. The detailed stacked structure of the display module DM will be described below in more detail.

The display panel DP may include a display region DA and a non-display region NDA respectively corresponding to the display region DA (see FIG. 1) and the non-display region NDA (see FIG. 1) of the electronic device ED. In this specification, the wording “a region/portion corresponds to a region/portion” may mean “overlapping each other”, and is not limited to having the same area.

The display panel DP may have a first hole region HA1 and a second hole region HA2 defined therein. The first hole region HA1 and the second hole region HA2 may have a light transmittance higher than the surroundings (e.g., than the area surrounding the first hole region HA1 and the second hole region HA2). The camera CA may be below the first hole region HA1, and the sensor SN may be below the second hole region HA2. Light passing through the first and second hole regions HA1 and HA2 may be provided to the camera CA and the sensor SN.

The display module DM may include a data driver DDV on the non-display region NDA of the display panel DP. The data driver DDV may be manufactured in a form of an integrated circuit chip and be mounted on the non-display region NDA. However, embodiments of the present disclosure are not limited thereto, and the data driver DDV may be mounted on a flexible circuit board connected or coupled to the display panel DP.

The electronic module EM and the power supply module PSM may be below the display device DD. In embodiments, the electronic module EM and the power supply module PSM may be connected or coupled to each other via an additional flexible circuit board. The electronic module EM may control an operation of the display device DD. The power supply module PSM may supply power to the electronic module EM.

The case EDC may accommodate the display device DD, the electronic module EM, and the power supply module PSM. The case EDC may include two first and second cases EDC1 and EDC2 (e.g., may include a first case EDC1 and a second case EDC2) so as to allow the display device DD to be folded. The first and second cases EDC1 and EDC2 may extend in the first direction DR1 and be provided in the second direction DR2.

In embodiments, the electronic device EDC may further include a hinge structure that connects or couples the first and second cases EDC1 and EDC2. The case EDC may be coupled to the window module WM. The case EDC may include the display device DD, the electronic module EM, and the power supply module PSM.

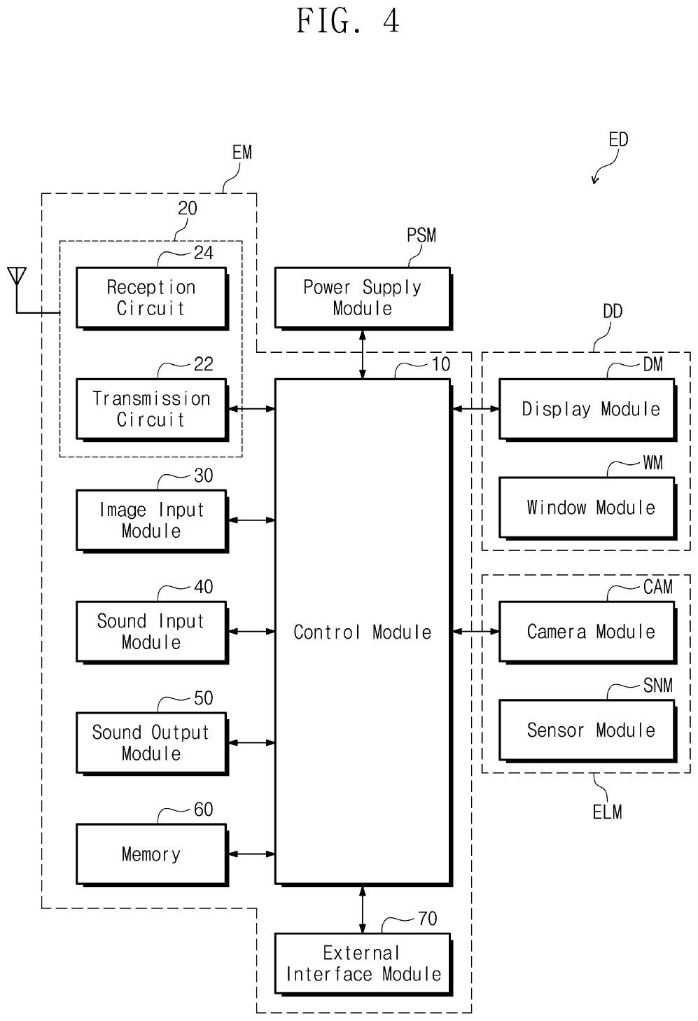

FIG. 4 is a block diagram of the electronic device illustrated in FIG. 3.

Referring to FIG. 4, an electronic device ED may include an electronic module EM, a power supply module PSM, a display device DD, and an electro-optical module ELM. The electronic module EM may include a control module 10, a wireless communication module 20, an image input module 30, a sound input module 40, a sound output module 50, a memory 60, an external interface module 70, and/or the like. The modules may be mounted on a circuit board or be electrically connected or coupled via a flexible circuit board. The electronic module EM may be electrically connected or coupled to the power supply module PSM.

The control module 10 may control an overall operation of the electronic device ED. For example, the control module 10 may activate or deactivate the display device DD according to a user's input. The control module 10 may control the image input module 30, the sound input module 40, and the sound output module 50, and/or the like according to a user's input. The control module 10 may include at least one microprocessor.

The wireless communication module 20 may transmit/receive wireless signals to/from another terminal through a Bluetooth and/or Wi-Fi line. The wireless communication module 20 may transmit/receive voice signals through any suitable, generally used communication line. The wireless communication module 20 may include a transmission circuit 22 which modulates and transmits a signal to be transmitted, and a reception circuit 24 which demodulates a received signal.

The image input module 30 may process image signals and convert the signals into image data displayable on the display device DD. The sound input module 40 may receive an input of an external sound signal via a microphone in a recording mode and/or voice recognition mode, etc., and convert the signal into electrical voice data. The sound output module 50 may convert sound data received from the wireless communication module 20 and/or sound data stored in the memory 60 and output the converted result to the outside.

The external interface module 70 may serve as an interface which is connected or coupled to an external charger, a wired/wireless data port, a card socket (for example, memory card, SIM/UIM card), and/or the like.

The power supply module PSM may supply power for an overall operation of the electronic device ED. The power supply module PSM may include any suitable, generally used battery device.

The electro-optical module ELM may be an electronic component which outputs and/or receives optical signals. The electro-optical module ELM may transmit and/or receive optical signals via some regions of the display device DD. In embodiments, the electro-optical module ELM may include a camera module CAM and a sensor module SNM. The camera module CAM may include the camera CA illustrated in FIG. 3. The sensor module SNM may include the sensor SN illustrated in FIG. 3.

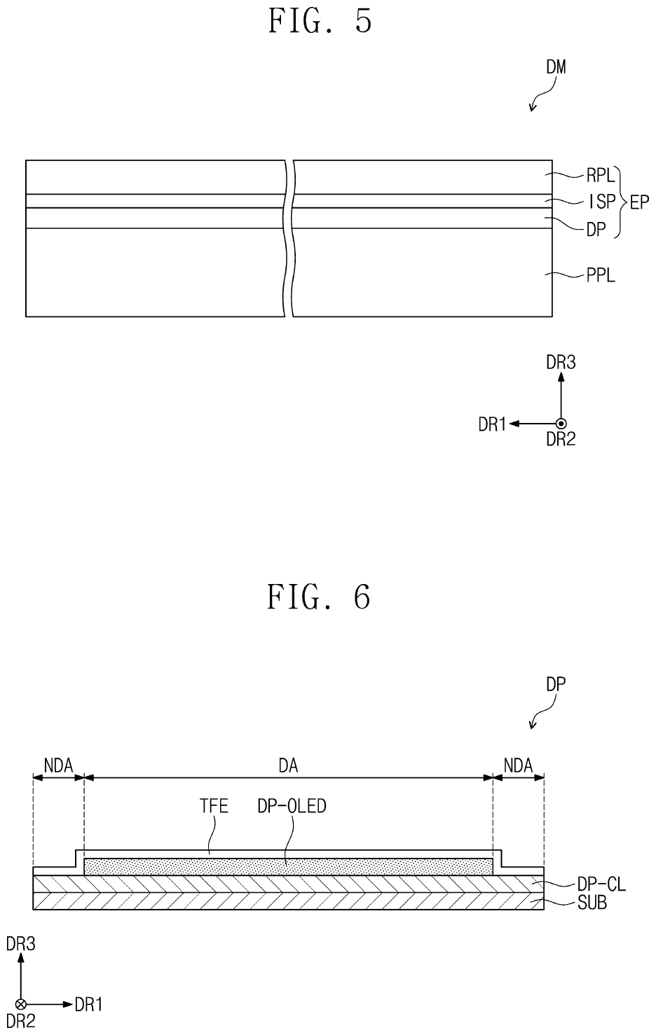

FIG. 5 is a schematic cross-sectional view of a display module illustrated in FIG. 3.

Referring to FIG. 5, a display module DM may include a display panel DP, an input-sensing unit ISP on the display panel DP, an anti-reflection layer RPL on the input-sensing unit ISP, and a panel protective layer PPL below the display panel DP. The display panel DP may be a flexible display panel. For example, the display panel DP may include a flexible board and a plurality of elements on the flexible board.

The display panel DP may be a light-emitting display panel, but is not particularly limited thereto. For example, the display panel DP may be an organic light-emitting display panel and/or an inorganic light-emitting display panel. A light-emitting layer of the organic light-emitting display panel may include an organic light-emitting material. A light-emitting layer of the inorganic light-emitting display panel may include quantum dots, quantum rods, and/or the like. Hereinafter, the display panel DP is described as an organic light-emitting display panel, but the present disclosure is not limited thereto.

The input-sensing unit ISP may include a plurality of sensor units for sensing an external input in a capacitive manner. The input-sensing unit ISP may be directly on (e.g., directly formed on) the display panel DP when the display module DM is manufactured.

The anti-reflection layer RPL may be on the input-sensing unit ISP. The anti-reflection layer RPL may be directly on (e.g., directly formed on) the input-sensing unit ISP when the display module DM is manufactured. The anti-reflection layer RPL may be defined as an external light anti-reflection film. The anti-reflection layer RPL may reduce the reflectance for external light which enters the display panel DP from above the display device DD.

For example, the input-sensing unit ISP may be directly on (e.g., directly formed on) the display panel DP, and the anti-reflection layer RPL may be directly on (e.g., directly formed on) the input-sensing unit ISP. However, embodiments of the present disclosure are not limited thereto. For example, the input-sensing unit ISP may be separately manufactured and be attached to the display panel DP via the adhesive layer. The anti-reflection layer RPL may be separately manufactured and be attached to the input-sensing unit ISP via the adhesive layer.

The display panel DP, the input-sensing unit ISP, and the anti-reflection layer RPL may be defined as an electronic panel EP.

The panel protective layer PPL may be below the display panel DP. The panel protective layer PPL may protect a lower part of the display panel DP. The panel protective layer PPL may include a flexible plastic material. For example, the panel protective layer PPL may include polyethylene terephthalate (PET).

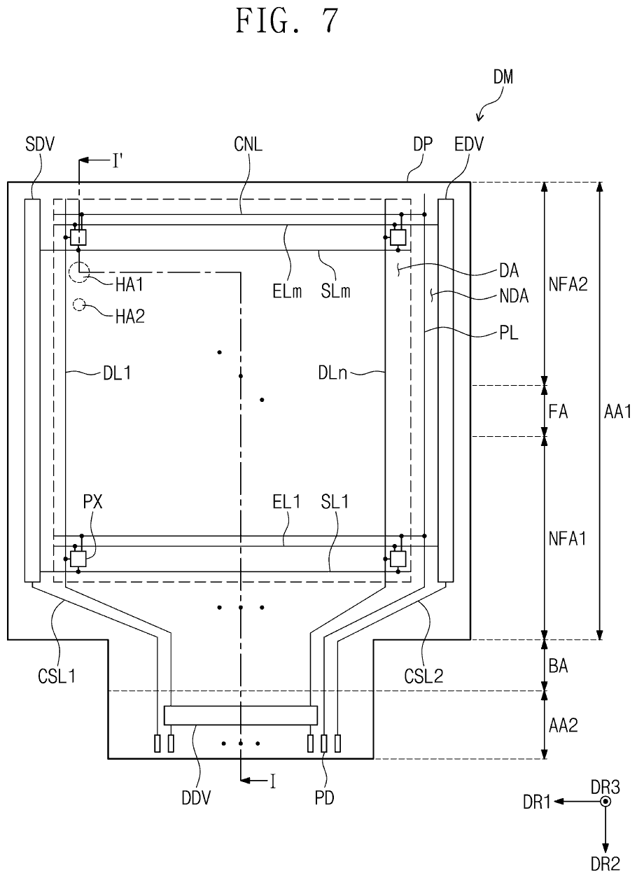

FIG. 6 is a cross-sectional view illustrating an example of a display panel illustrated in FIG. 5.

For example, FIG. 6 illustrates a cross section of a display panel DP when viewed in the second direction DR2.

Referring to FIG. 6, the display panel DP may include a substrate SUB, a circuit element layer DP-CL on the substrate SUB, a display element layer DP-OLED on the circuit element layer DP-CL, and a thin-film encapsulation layer TFE on the display element layer DP-OLED.

The substrate SUB may include a display region DA and a non-display region NDA around the display region DA. The substrate SUB may include glass and/or a flexible plastic material such as polyimide (PI). The display element layer DP-OLED may be on the display region DA.

A plurality of pixels may be on the circuit element layer DP-CL and the display element layer DP-OLED. The pixels may each include a transistor on the circuit element layer DP-CL, and a light-emitting element on the display element layer DP-OLED and connected or coupled to the transistor.

The thin-film encapsulation layer TFE may be on the circuit element layer DP-CL so as to cover the light-emitting element layer DP-OLED. The thin-film encapsulation layer TFE may protect the pixels against moisture, oxygen, and/or external foreign substances.

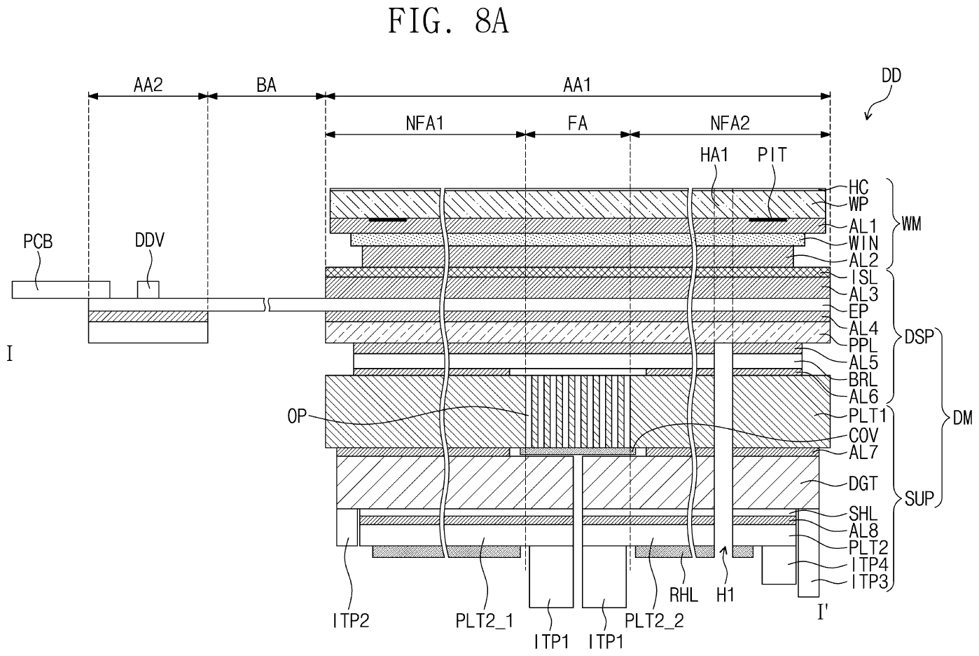

FIG. 7 is a plan view of the display panel illustrated in FIG. 6.

Referring to FIG. 7, a display module DM may include a display panel DP, a scan driver SDV, a data driver DDV, and an emission driver EDV.

The display panel DP may include a first region AA1, a second region AA2, and a bending region BA between the first region AA1 and the second region AA2. The bending region BA may extend in the first direction DR1, and the first region AA1, the bending region BA, and the second region AA2 may be provided in the second direction DR2.

The first region AA1 may include a display region DA and a non-display region NDA around the display region DA. The non-display region NDA may surround the display region DA. The display region DA may display images, and the non-display region NDA may not display images. The second region AA2 and the bending region BA may not display images. The first and second hole regions HA1 and HA2 described above may be defined in the display region DA. The images may be displayed while overlapping the first and second holes HA1 and HA2.

When viewed in the first direction DR1, the first region AA1 may include a first non-folding region NFA1, a second non-folding region NFA2, and a folding region FA between the first non-folding region NFA1 and the second non-folding region NFA2. The first and second hole regions HA1 and HA2 described above may be defined in the second non-folding region NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power supply line PL, connection lines CNL, and a plurality of pads PD. As described herein, m and n are natural numbers. The pixels PX may be in the display region DA and be connected or coupled to the scan lines SL1 to SLm, the data lines DL1 to DLn, and the emission lines EL1 to ELm.

The scan driver SDV and the emission driver EDV may be in the non-display region NDA. The scan driver SDV and the emission driver EDV may be in the non-display region NDA adjacent to each of both sides (e.g., two opposing sides), of the first region AA1, which are opposed to each other in the first direction DR1. The data driver DDV may be in the second region AA2. The data driver DDV may be manufactured in a form of an integrated circuit chip and be mounted on the second region AA2.

The scan lines SL1 to SLm may extend in the first direction DR1 to be connected or coupled to the scan driver SDV. The data lines DL1 to DLn may extend in the second direction DR2 to be connected or coupled to the data driver DDV via the bending region BA. The emission lines EL1 to ELm may extend in the first direction DR1 to be connected or coupled to the emission driver EDV.

The power supply line PL may extend in the second direction DR2 and be in the non-display region NDA. The power supply line PL may be between the display region DA and the emission driver EDV, but is not limited thereto. The power supply line PL may be between the display region DA and the scan driver SDV.

The power supply line PL may extend to the second region AA2 via the bending region BA. When viewed on a plane, the power supply line PL may extend toward a lower end of the second region AA2. The power supply line PL may receive a driving voltage.

The connection lines CNL may extend in the first direction DR1 and be arranged in the second direction DR2. The connection lines CNL may be connected or coupled to the power supply line PL and the pixels PX. The driving voltage may be applied to the pixels PX via the power supply line PL and the connection lines CNL which are connected or coupled to each other.

The first control line CSL1 may be connected or coupled to the scan driver SDV and extend toward a lower end of the second region AA2 via the bending region BA. The second control line CSL2 may be connected or coupled to the emission driver EDV and extend toward the lower end of the second region AA2 via the bending region BA. The data driver DDV may be between the first control line CSL1 and the second control line CSL2.

When viewed on a plane, the pads PD may be adjacent to the lower end of the second region AA2. The data driver DDV, the power supply line PL, the first control line CSL1, and the second control line CSL2 may be connected or coupled to the pads PD.

The data lines DL1 to DLn may be connected or coupled to the corresponding pads PD via the data driver DDV. For example, the data lines DL1 to DLn may be connected or coupled to the data driver DDV, and the data driver DDV may be connected or coupled to the pads PD respectively corresponding to the data lines DL1 to DLn.

In embodiments, a printed circuit board may be connected or coupled to the pads PD, and a timing controller and a voltage generator may be on the printed circuit board. The timing controller may be manufactured as an integrated circuit chip and be mounted on the printed circuit board. The timing controller and the voltage generator may be connected or coupled to the pads PD via the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate a driving voltage.

The scan control signal may be provided to the scan driver SDV via the first control line CSL1. The emission control signal may be provided to the emission driver EDV via the second control line CSL2. The data control signal may be provided to the data driver DDV. The timing controller may receive image signals from the outside, convert data formats of the image signals so as to meet interface specifications of the data driver DDV, and provide the converted signals to the data driver DDV.

The scan driver SDV may generate a plurality of scan signals in response to a scan control signal. The scan signals may be applied to the pixels PX via the scan lines SL1 to SLm. The scan signals may be sequentially applied to the pixels PX.

The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive data voltages in response to the scan signals. The pixels PX may display an image by emitting light having a luminance corresponding to the data voltages in response to the emission signals. The emission time of the pixels PX may be controlled by the emission signals.

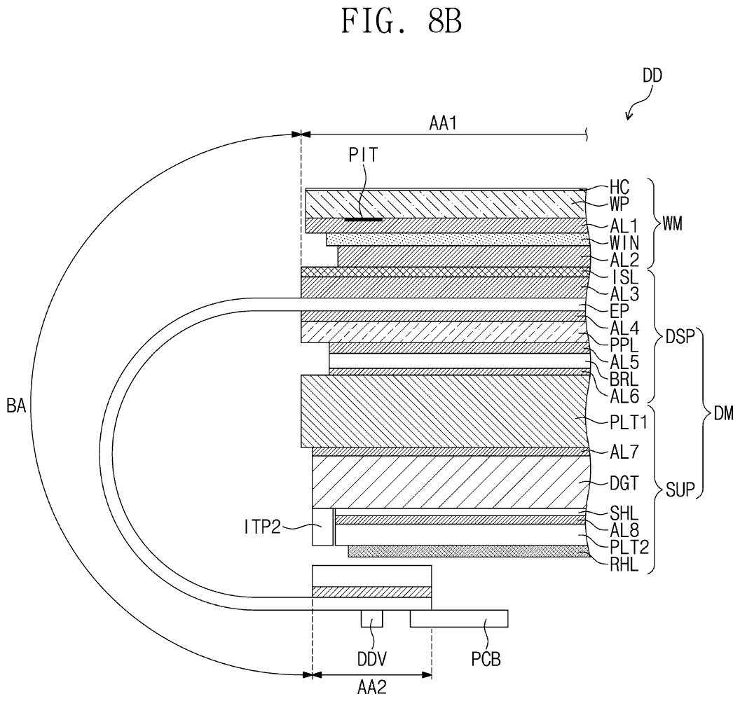

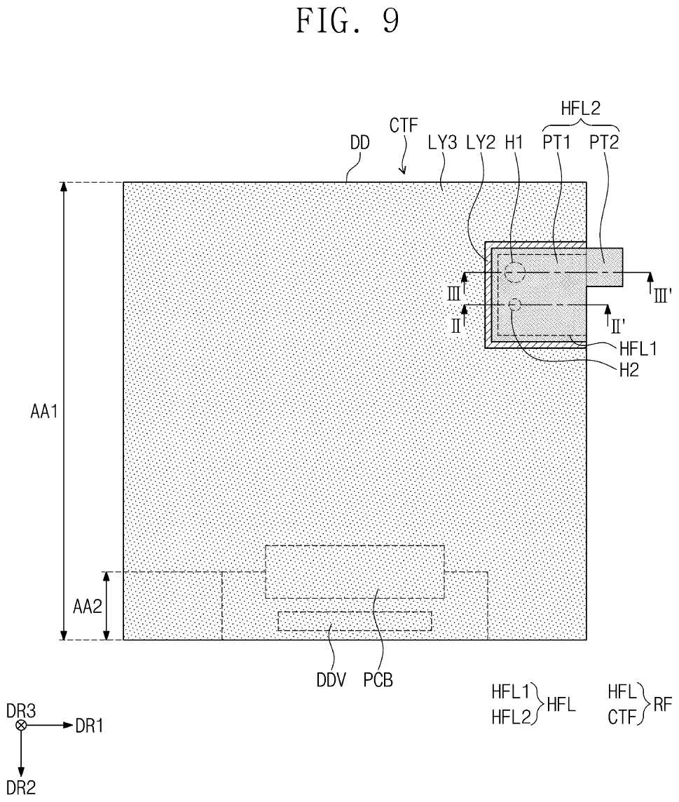

FIG. 8A is a cross-sectional view taken along line I-I′ illustrated in FIG. 7. FIG. 8B is a cross-sectional view illustrating a state in which a bending region illustrated in FIG. 8A is bent.

For example, FIG. 8A illustrates both a cross section of a display module DM and a cross section of a window module WM, which are taken along line I-I′.

Referring to FIG. 8A, a display device DD may include a display module DM and a window module WM on the display module DM. The display module DM may be a flexible display module. The display module DM may include a first non-folding region NFA1, a folding region FA, and a second non-folding region NFA2.

The display module DM may include a display part DSP and a support part SUP. The support part SUP may be below the display part DSP and support the display part DSP.

The window module WM may include a window WIN, a window protective layer WP, a hard coating layer HC, and first and second adhesive layers AL1 and AL2. The display part DSP may include an electronic panel EP, an impact absorbing layer ISL, a panel protective layer PPL, a barrier layer BRL, and third to sixth adhesive layers AL3 to AL6. The components of the electronic panel EP and the panel protective layer PPL have been described above in detail with reference to FIG. 5, and the description thereof may not be repeated here.

The impact absorbing layer ISL may be on the electronic panel EP. The impact absorbing layer ISL absorbs an external impact applied from above the display device DD toward the electronic panel EP, and may thus protect the electronic panel EP. The impact absorbing layer ISL may be manufactured in a form of a stretched film.

The impact absorbing layer ISL may include a flexible plastic material. The flexible plastic material may be defined as a synthetic resin film. For example, the impact absorbing layer ISL may include a flexible plastic material such as polyimide (PI) and/or polyethyleneterephthalate (PET).

The window WIN may be on the impact absorbing layer ISL. The window WIN may protect the electronic panel EP against external scratches. The window WIN may have an optically transparent property. The window WIN may include glass. However, embodiments of the present disclosure are not limited thereto, and the window WIN may include a synthetic resin film.

The window WIN may have a single- or multi-layered structure. For example, the window WIN may include a plurality of synthetic resin films bonded with an adhesive, or may include a glass substrate and a synthetic resin film bonded with an adhesive.

The window protective layer WP may be on the window WIN. The window protective layer WP may include a flexible plastic material such as polyimide and/or polyethyleneterephthalate. The hard coating layer HC may be on an upper surface of the window protective layer WP.

A printed layer PIT may be on a lower surface of the window protective layer WP. The printed layer PIT may be black, but a color of the printed layer PIT is not limited thereto. The printed layer PIT may be adjacent to a border of the window protective layer WP.

The barrier layer BRL may be below the panel protective layer PPL. The barrier layer BRL may enhance resistance against a compressive force caused by external pressure. Accordingly, the barrier layer BRL may serve to prevent or reduce deformation of the electronic panel EP. The barrier layer BRL may include a flexible plastic material such as polyimide and/or polyethyleneterephthalate.

The barrier layer BRL may have a color which absorbs light. For example, the barrier layer BRL may be black. In this case, when the display module DM is viewed from above, components below the barrier layer BRL may be invisible.

The first adhesive layer AL1 may be between the window protective layer WP and the window WIN. The window protective layer WP and the window WIN may be bonded to each other via the first adhesive layer AL1. The first adhesive layer AL1 may cover the printed layer PIT.

The second adhesive layer AL2 may be between the window WIN and the impact absorbing layer ISL. The window WIN and the impact absorbing layer ISL may be bonded to each other via the second adhesive layer AL2.

The third adhesive layer AL3 may be between the impact absorbing layer ISL and the electronic panel EP. The impact absorbing layer ISL and the electronic panel EP may be bonded to each other via the third adhesive layer AL3.

The fourth adhesive layer AL4 may be between the electronic panel EP and the panel protective layer PPL. The electronic panel EP and the panel protective layer PPL may be bonded to each other via the fourth adhesive layer AL4.

The fifth adhesive layer AL5 may be between the panel protective layer PPL and the barrier layer BRL. The panel protective layer PPL and the barrier layer BRL may be bonded to each other via the fifth adhesive layer AL5.

The sixth adhesive layer AL6 may be between the barrier layer BRL and the support part SUP. In embodiments, a first support plate PLT1 of the support part SUP may be below the barrier layer BRL, and the sixth adhesive layer AL6 may be between the barrier layer BRL and the first support plate PLT1. The barrier layer BRL and the first support plate PLT1 may be bonded to each other via the sixth adhesive layer AL6.

Hereinafter, in this specification, the term “thickness” may represent a value measured in the third direction DR3, and the term “width” may represent a value measured in the first direction DR1 or the second direction DR2, which is a horizontal direction.

The sixth adhesive layer AL6 may overlap the first and second non-folding regions NFA1 and NFA2 and may not overlap the folding region FA. For example, the sixth adhesive layer AL6 may not be provided in the folding region FA.

The first to sixth adhesive layers AL1 to AL6 may include a transparent adhesive such as a pressure sensitive adhesive (PSA) and/or an optically clear adhesive (OCA), but a type (or kind) of adhesive is not limited thereto.

The thickness of the panel protective layer PPL may be smaller than the thickness of the window protective layer WP, and the thickness of the barrier layer BRL may be smaller than the thickness of the panel protective layer PPL. The thickness of the electronic panel EP may be smaller than the thickness of the barrier layer BRL, and may be the same as the thickness of the window WIN. The thickness of the impact absorbing layer ISL may be smaller than the thickness of the electronic panel EP.

The thickness of the first adhesive layer AL1 may be the same as the thickness of the barrier layer BRL, and the thickness of each of the second adhesive layer AL2 and the third adhesive layer AL3 may be the same as the thickness of the panel protective layer PPL. The thickness of the fourth adhesive layer AL4 may be the same as the thickness of the fifth adhesive layer AL5.

The thickness of each of the fourth adhesive layer AL4 and the fifth adhesive layer AL5 may be smaller than the thickness of the electronic panel EP and may be greater than the thickness of the impact absorbing layer ISL. The sixth adhesive layer AL6 may have a thickness smaller than that of the impact absorbing layer ISL. The thickness of the hard coating layer HC may be smaller than the thickness of the sixth adhesive layer AL6.

The electronic panel EP, the impact absorbing layer ISL, the panel protective layer PPL, and the third and fourth adhesive layers AL3 and AL4 may have the same width. The window protective layer WP and the first adhesive layer AL1 may have the same width. The barrier layer BRL and the fifth and sixth adhesive layers AL5 and AL6 may have the same width.

The widths of the electronic panel EP, the impact absorbing layer ISL, the panel protective layer PPL, and the third and fourth adhesive layers AL3 and AL4 may be greater than the widths of the window protective layer WP and the first adhesive layer AL1. The borders of the electronic panel EP, the impact absorbing layer ISL, the panel protective layer PPL, and the third and fourth adhesive layers AL3 and AL4 may be disposed further outward than the borders of the window protective layer WP and the first adhesive layer AL1.

The widths of the window WIN and the second adhesive layer AL2 may be smaller than the widths of the window protective layer WP and the first adhesive layer AL1. The width of the second adhesive layer AL2 may be smaller than the width of the window WIN. The border of the window WIN may be provided further inward than the borders of the window protective layer WP and the first adhesive layer AL1. The border of the second adhesive layer AL2 may be provided further inward than the border of the window WIN.

The widths of the barrier layer BRL and the fifth and sixth adhesive layers AL5 and AL6 may be smaller than the widths of the window protective layer WP and the first adhesive layer AL1. The borders of the barrier layer BRL and the fifth and sixth adhesive layers AL5 and AL6 may be provided further inward than the borders of the window protective layer WP and the first adhesive layer AL1.

The support part SUP may include the first support plate PLT1, a second support plate PLT2, a cover layer COV, a digitizer DGT, a shielding layer SHL, a heat dissipation layer RHL, seventh and eighth adhesive layers AL7 and AL8, and a plurality of first to fourth insulating tapes ITP1 to ITP4.

The first support plate PLT1 may be below the electronic panel EP and support the electronic panel EP. The first support plate PLT1 may have greater rigidity than the display part DSP. The first support plate PLT1 may include a non-metallic material. For example, the first support plate PLT1 may include a reinforced fiber composite material. The reinforced fiber composite material may be a carbon fiber reinforced plastic (CFRP) and/or a glass fiber reinforced plastic (GFRP).

The first support plate PLT1 may include the reinforced fiber composite material, thereby achieving lightness (e.g., may be relatively lighter than a metal support plate made of a metal material). The first support plate PLT1 according to an embodiment includes the reinforced fiber composite material, and may thus have not only a lighter weight than a metal support plate made of a metal material, but also have modulus and strength similar to those of the metal support plate.

In embodiments, the first support plate PLT1 includes the reinforced fiber composite material, and thus shape processing (e.g., shaping) of the first support plate PLT1 may be easily performed compared to the metal support plate. For example, the first support plate PLT1 including the reinforced fiber composite material may be more easily processed through a laser process and/or micro blast process than a metal support plate made of a metal material.

A plurality of openings OP may be defined in a portion of the first support plate PLT1 overlapping the folding region FA. The openings OP may be formed passing through portions of the first support plate PLT1 in the third direction DR3. The openings OP may be formed through the above-described laser process and/or micro blast process.

The openings OP are defined in a portion of the first support plate PLT1 overlapping the folding region FA, and thus the flexibility of the portion of the first support plate PLT1 overlapping the folding region FA may be enhanced. As a result, the first support plate PLT1 may be easily folded with respect to the folding region FA. The width of the portion in which the openings OP are formed may be smaller than the width of a portion in which the sixth adhesive layer AL6 is opened.

The cover layer COV may be below the first support plate PLT1. The cover layer COV may cover, below the first support plate PLT1, the openings OP defined in the first support plate PLT1. The cover layer COV may overlap the folding region FA and may not overlap the first and second non-folding regions NFA1 and NFA2. In embodiments, the cover layer COV may not be in the first and second non-folding regions NFA1 and NFA2. The cover layer COV may be in contact with a lower surface of the portion, of the first support plate PLT1, in which the openings OP are formed.

The cover layer COV may have a lower elastic modulus than the first support plate PLT1. For example, the cover layer COV may include thermoplastic polyurethane and/or rubber, but a material of the cover layer COV is not limited thereto. The cover layer COV may be manufactured in a form of a sheet and be attached to the first support plate PLT1.

The digitizer DGT may be below the first support plate PLT1. The cover layer COV may be between the first support plate PLT1 and the digitizer DGT. The cover layer COV may be spaced apart from an upper surface of the digitizer DGT. The digitizer DGT is a device which may receive information about the position indicated by the user on a display surface. The digitizer DGT may be implemented in an electromagnetic manner (or electromagnetic resonance manner). For example, the digitizer DGT may include a digitizer sensor substrate including a plurality of coils. However, embodiments of the present disclosure are not limited thereto, and the digitizer DGT may also be implemented in an active electrostatic manner.

When a user moves a pen on the display device DD, the pen is driven by an alternating current signal so as to cause a vibrating magnetic field, and thus the vibrating magnetic field may induce a signal to coils. A position of the pen may be detected through a signal induced to the coils. The digitizer DGT may determine the position of the pen by detecting an electromagnetic change caused by the approach of the pen.

When the first support plate PLT1 which is on the digitizer DGT and adjacent to the digitizer DGT includes metal, the sensitivity of the digitizer DGT may be reduced due to the metal. For example, when the signal delivered on the display device DD is blocked or reduced by signal interference caused by the metal support plate, the digitizer DGT may not operate appropriately. However, in embodiments of the present disclosure, the first support plate PLT1 on the digitizer DGT includes a non-metallic reinforced fiber composite material, and thus the digitizer DGT may operate suitably or appropriately.

The digitizer DGT may be separated into two portions in the folding region FA. The separated portions of the digitizer DGT may each be connected or coupled to a digitizer driver via flexible circuit boards.

The shielding layer SHL may be below the digitizer DGT. The shielding layer SHL may include metal. For example, the shielding layer SHL may include copper, but a metal material of the shielding layer SHL is not limited thereto. The shielding layer SHL may be separated into two portions in the folding region FA. The separated portions of the shielding layer SHL may be respectively below the portions, of the digitizer DGT, which are separated from each other.

The shielding layer SHL may shield electromagnetism which may be applied to the digitizer DGT below the display device DD. The shielding layer SHL may also be defined as an electromagnetic shielding layer. The shielding layer SHL including metal may function as a heat dissipation layer.

The second support plate PLT2 may be below the shielding layer SHL. The second support plate PLT2 may have greater rigidity than the display part DSP. The second support plate PLT2 may include a metal material such as stainless steel (for example, SUS 316), but a metal material of the second support plate PLT2 is not limited thereto. Additionally, embodiments of the present disclosure are not limited thereto, and the second support plate PLT2 may include a non-metallic material such as plastic.

The second support plate PLT2 may be separated into two portions in the folding region FA. For example, the second support plate PLT2 may include a (2_1)-th support plate PLT2_1 overlapping the first non-folding region NFA1 and a (2_2)-th support plate PLT2_2 overlapping the second non-folding region NFA2.

The (2_1)-th support plate PLT2_1 may support the first non-folding region NFA1. The (2_2)-th support plate PLT2_2 may support the second non-folding region NFA2. The (2_1)-th support plate PLT2_1 and the (2_2)-th support plate PLT2_2 may extend to the folding region FA and be adjacent to each other in the folding region FA.

The (2_1)-th support plate PLT2_1 and the (2_2)-th support plate PLT2_2 may be spaced apart from each other below the folding region FA. The (2_1)-th support plate PLT2_1 and the (2_2)-th support plate PLT2_2 may support, below the folding region FA, a portion of the first support plate PLT1 in which the openings OP are defined. When pressure is applied to the first support plate PLT1 from above, the (2_1)-th support plate PLT2_1 and the (2_2)-th support plate PLT2_2 may prevent or reduce deformation of the portion of the first support plate PLT1, in which the openings OP are defined. In embodiments, the (2_1)-th and (2_2)-th support plates PLT2_1 and PLT2_2 may perform a heat dissipation function.

The heat dissipation layer RHL may be under the second support plate PLT2. The heat dissipation layer RHL may be separated into two portions in the folding region FA. The separated portions of the heat dissipation layer RHL may be respectively under the (2_1)-th and (2_2)-th support plates PLT2_1 and PLT2_2.

The heat dissipation layer RHL may perform a heat dissipation function. For example, the heat dissipation layer RHL may include graphite, but a material of the heat dissipation layer RHL is not limited thereto. The heat dissipation layer RHL performs a heat dissipation function together with the second support plate PLT2 and the shielding layer SHL, and thus the heat dissipation performance of the display device DD may be improved.

The first to fourth insulating tapes ITP1 to ITP4 may be under the digitizer DGT and the second support plate PLT2. The first to fourth insulating tapes ITP1 to ITP4 may include an insulating material (e.g., an electrically insulating material).

Two first insulating tapes ITP1 may be adjacent to mutually face one side of the (2_1)-th support plate PLT2_1 and one side of the (2_2)-th support plate PLT2_2 and respectively under the (2_1)-th and (2_2)-th support plates PLT2_1 and PLT2_2.

The second insulating tape ITP2 and the third insulating tape ITP3 may be adjacent to respective both sides (e.g., two opposing sides) of the digitizer DGT and under the digitizer DGT. The second insulating tape ITP2 may be adjacent to a border of the (2_1)-th support plate PLT2_1, and the third insulating tape ITP3 may be adjacent to a border of the (2_2)-th support plate PLT2_2.

The fourth insulating tape ITP4 may be adjacent to the other side of the (2_2)-th support plate PLT2_2 which is opposite to the one side of the (2_2)-th support plate PLT2_2. The fourth insulating tape ITP4 may be under the (2_2)-th support plate PLT2_2.

The shielding layer SHL, the second support plate PLT2, the heat dissipation layer RHL, the first insulating tapes ITP1, and the fourth insulating tape ITP4 may be between the second insulating tape ITP2 and the third insulating tape ITP3. One of the heat dissipation layers RHL separated from each other may be between the first insulating tape ITP1 and the fourth insulating tape ITP4, which are under the (2_2)-th support plate PLT2_2. The other of the heat dissipation layers RHL separated from each other may be between the first insulating tape ITP1 under the (2_1)-th support plate PLT2_1 and the second insulating tape ITP2 under the digitizer DGT.

In embodiments, magnets may be below the display module DM to maintain a folded state when the electronic device ED is folded. The magnets may be adjacent to a border of the electronic device ED. The folded state of the electronic device ED may be maintained due to the magnetic forces of the magnets.

When the magnetic properties of the magnets are transmitted to the digitizer DGT, the digitizer DGT may not operate appropriately. The first to fourth insulating tapes ITP1 to ITP4 may block or reduce the magnetic properties of the magnets, on the border of the electronic device ED, from being transmitted to the digitizer DGT. The first to fourth insulating tapes ITP1 to ITP4 may be defined as magnetic property blocking tapes.

The seventh adhesive layer AL7 may be between the first support plate PLT1 and the digitizer DGT. The first support plate PLT1 and the digitizer DGT may be bonded to each other via the seventh adhesive layer AL7. The seventh adhesive layer AL7 may not be in the folding region FA. In embodiments, the seventh adhesive layer AL7 may be opened in the folding region FA. The cover layer COV described above may be in the opening of the seventh adhesive layer AL7. The seventh adhesive layer AL7 is not below the folding region FA, and thus a folding operation of the support part SUP may be more easily performed.

The eighth adhesive layer AL8 may be between the shielding layer SHL and the second support plate PLT2. The shielding layer SHL and the second support plate PLT2 may be bonded to each other via the eighth adhesive layer AL8. Portions of the eighth adhesive layer AL8 may be separated from each other in the folding region FA. The separated portions of the eighth adhesive layer AL8 may respectively be between the separated portions of the shielding layer SHL and the (2_1)-th and (2_2)-th support plates PLT2_1 and PLT2_2. The eighth adhesive layer AL8 may be between the second insulating tape ITP2 and the third insulating tape ITP3.

The width of the first support plate PLT1 may be substantially the same as the width of the electronic panel EP. The widths of the digitizer DGT and the seventh adhesive layer AL7 may be smaller than the width of the first support plate PLT1. The borders of the digitizer DGT and the seventh adhesive layer AL7 may be provided further inward than the border of the first support plate PLT1.

The widths of the shielding layer SHL, the eighth adhesive layer AL8, and the second support plate PLT2 may be smaller than the width of the digitizer DGT. The borders of the shielding layer SHL, the eighth adhesive layer AL8, and the second support plate PLT2 may be provided further inward than the border of the digitizer DGT.

The thickness of the first support plate PLT1 may be greater than the thickness of the digitizer DGT, and the thickness of the digitizer DGT may be greater than the thickness of the second support plate PLT2. The thickness of the second support plate PLT2 may be greater than the thickness of the heat dissipation layer RHL, and the thickness of the heat dissipation layer RHL may be greater than the thickness of each of the seventh and eighth adhesive layers AL7 and AL8.

The thickness of each of the seventh and eighth adhesive layers AL7 and AL8 may be greater than the thickness of the shielding layer SHL, and the thickness of the shielding layer SHL may be greater than the thickness of the cover layer COV. The thickness of the cover layer COV may be the same as the thickness of the sixth adhesive layer AL6.

The thickness of each of the first insulating tapes ITP1 may be smaller than the thickness of the first support plate PLT1, and may be greater than the thickness of the digitizer DGT. The thickness of the third insulating tape ITP3 may be greater than the thickness of the first support plate PLT1. The thickness of the fourth insulating tape ITP4 may be smaller than the thickness of each of the first insulating tapes ITP1. The thickness of the second insulating tape ITP2 may be smaller than the thickness of the fourth insulating tape ITP4.

The seventh and eighth adhesive layers AL7 to AL8 may include a pressure sensitive adhesive (PSA) and/or an optically clear adhesive (OCA), but a type (or kind) of adhesive is not limited thereto.

A first hole H1 may be defined in a portion of the display module DM overlapping a first hole region HA1. The first hole H1 may be defined in a region from the heat dissipation layer RHL to a portion before the panel protective layer PPL. For example, the first hole H1 may be integrally defined in the barrier layer BRL, the first support plate PLT1, the digitizer DGT, the shielding layer SHL, the second support plate PLT2, the heat dissipation layer RHL, and the fifth to eighth adhesive layers AL5 to AL8.

In embodiments, a second hole may be formed in a second hole region HA2, and the second hole may also be defined, as similar to the first hole H1, in a region from the heat dissipation layer RHL to a portion before the panel protective layer PPL. The camera CA described above may be defined in the first hole H1, and the sensor SN described above may be defined in the second hole.

Referring to FIG. 8B, the panel protective layer PPL and the fourth adhesive layer AL4 may not be below the bending region BA. The panel protective layer PPL and the fourth adhesive layer AL4 may be below the second region AA2 of the electronic panel EP. The data driver DDV may be on the second region AA2 of the electronic panel EP.

The printed circuit board PCB may be connected or coupled to the second region AA2 of the electronic panel EP. A printed circuit board PCB may be connected or coupled to one side of the second region AA2. As the bending region BA is bent, the second region AA2 may be below the first region AA1. In embodiments, the data driver DDV and the printed circuit board PCB may be below the first region AA1.

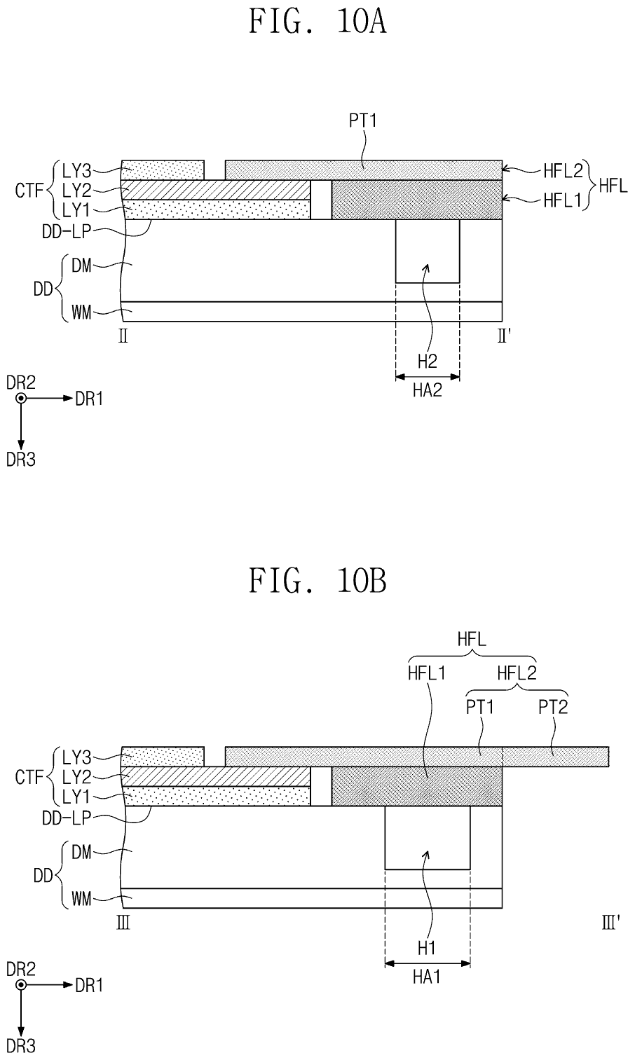

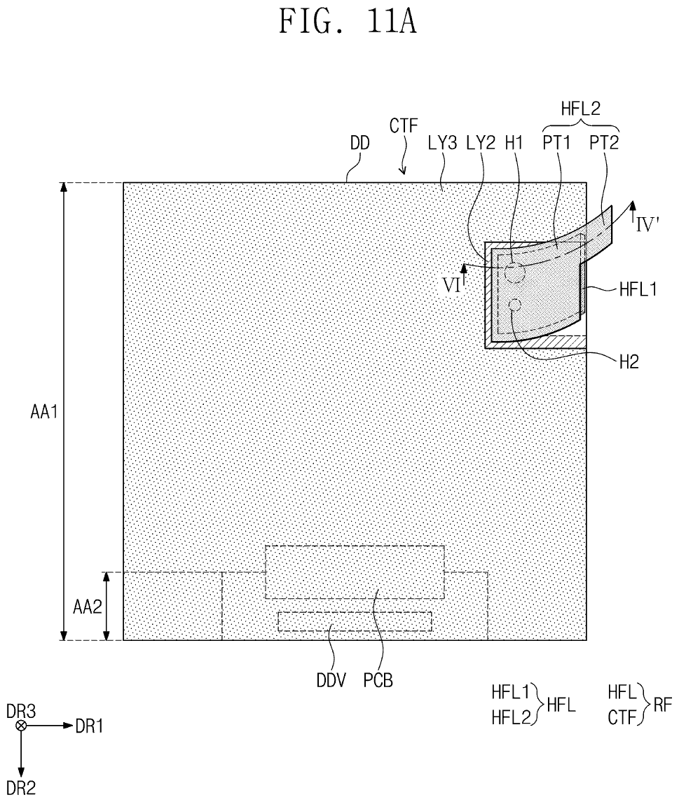

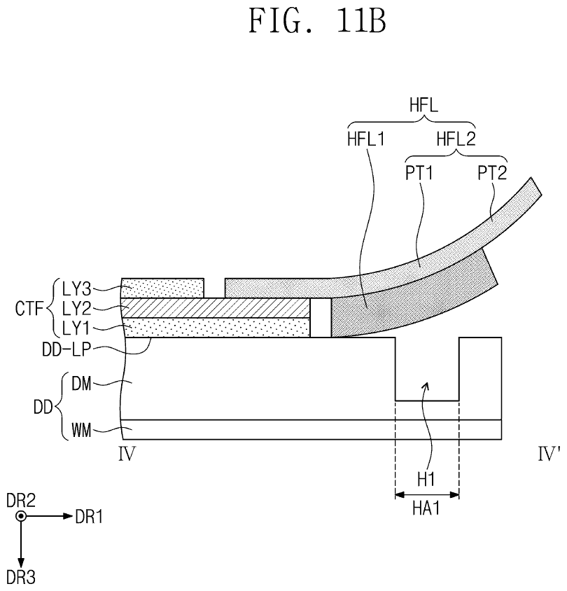

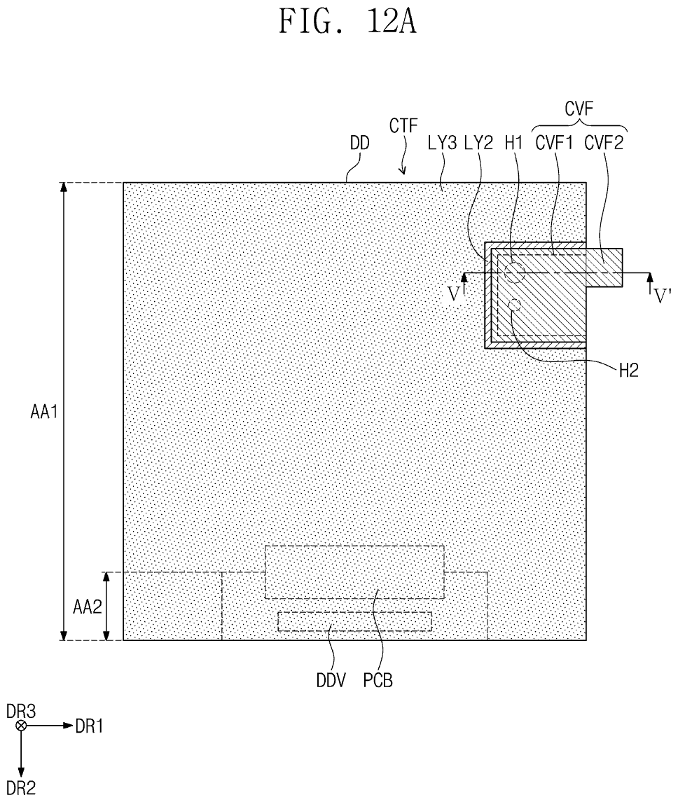

FIG. 9 is a view illustrating a release film according to an embodiment of the present disclosure. FIG. 10A is a cross-sectional view taken along line II-II′ illustrated in FIG. 9. FIG. 10B is a cross-sectional view taken along line III-III′ illustrated in FIG. 9. FIGS. 11A-11B are views illustrating a hole film being detached from the display device of FIG. 9.

For example, FIG. 9 and FIG. 11A are plan views illustrating a rear surface of a display device DD.

For example, FIG. 11B is a cross-sectional view taken along line IV-IV′ illustrated in FIG. 11A.

For example, FIG. 9 and FIG. 11A are plan views illustrating a state in which the bending region BA (see FIG. 7) of the display panel DP (see FIG. 7) is bent and a second region AA2 is on the rear surface of the display device DD.

For example, in FIG. 9 and FIG. 11A, a first hole H1, a second hole H2, the second region AA2, a first hole film HFL1, a printed circuit board PCB, and a data driver DDV are shown as dotted lines.

For example, in FIGS. 10A-10B, a display module DM and a window module WM each are briefly illustrated as a single layer.

The display device DD of FIGS. 9-10B is identical or similar to the display device DD of FIGS. 8A-8B, and thus description thereof may not be repeated here or may be abbreviated.

Referring to FIG. 9, FIG. 10A, and FIG. 10B, when the display device DD is conveyed to another process, a release film RF may protect a rear surface DD-LP of the display device DD against external impacts and/or scratches. The release film RF may be on the rear surface DD-LP of the display device DD. For example, the rear surface DD-LP of the display device DD may be defined as a rear surface of the display module DM.

The release film RF may include a protective film CTF and a hole film HFL. The protective film CTF may be on the rear surface DD-LP of the display device DD and in a periphery of the first hole H1 and the second hole H2, which are defined in the display device DD. The protective film CTF may not overlap the first hole H1 and the second hole H2.

The protective film CTF may include a first protective film LY1, a second protective film LY2, and a third protective film LY3. As illustrated in FIGS. 10A-10B, the first protective film LY1, the second protective film LY2, and the third protective film LY3 may be sequentially stacked on the rear surface of the display device DD in the third direction DR3. In embodiments, the first protective film LY1 may be on the rear surface DD-LP of the display device DD. The second protective film LY2 may be on an upper surface of the first protective film LY1. The third protective film LY3 may be on the second protective film LY2. The upper surface of the first protective film LY1 and an upper surface of the second protective film LY2 may be defined as a surface opposed to a lower surface facing the rear surface DD-LP of the display device DD.

For example, the first protective film LY1, the second protective film LY2, and the third protective film LY3 may have the same thickness in the third direction DR3, but are not limited thereto. A thickness of one film among the first protective film LY1, the second protective film LY2, and the third protective film LY3 may be different from a thickness of another film.

In embodiments, a lower surface of the first protective film LY1 may be adhered to the rear surface DD-LP of the display device DD via an adhesive agent. For example, an adhesive strength of the adhesive agent may be about 10 gf/in to about 20 gf/in.

In embodiments, because the adhesive agent is between the first protective film LY1 and the second protective film LY2, and between the second protective film LY2 and the third protective film LY3, the first protective film LY1 and the second protective film LY2 may be adhered to each other, and the second protective film LY2 and the third protective film LY3 may be adhered to each other.

When viewed on a plane, the border of the first protective film LY1 may overlap the border of the second protective film LY2 in the third direction DR3. When viewed on a plane, the area of the first protective film LY1 and the area of the second protective film LY2 may be greater than the area of the third protective film LY3. The border of the second protective film LY2 may be exposed to the outside from the third protective film LY3. The border of the first protective film LY1 and the border of the second protective film LY2 may be more adjacent (e.g., closer) to the first hole H1 than the border of the third protective film LY3.

The hole film HFL may be on the rear surface DD-LP of the display device DD. When viewed on a plane, the hole film HFL may be adjacent to the protective film CTF. When viewed on a plane, the border of the hole film HFL may have a shape corresponding to the border of the protective film CTF which faces the border of the hole film HFL.

The hole film HFL may overlap the first hole H1 and the second hole H2. A portion of the hole film HFL may be on the second protective film LY2. Another portion of the hole film HFL may extend further outward than the border of the display device DD.

The hole film HFL may include a first hole film HFL1 and a second hole film HFL2. The first hole film HFL1 may overlap the first hole H1 and the second hole H2. The first hole film HFL1 may be on the rear surface DD-LP of the display device DD. The first hole film HFL1 may cover the first hole H1 and the second hole H2 defined in the display device DD. The first hole film HFL1 may prevent or reduce introduction of foreign materials into the first hole H1 and the second hole H2.

An adhesive agent may not be between a lower surface of the first hole film HFL1 and the rear surface DD-LP of the display device DD. The lower surface of the first hole film HFL1 may not be adhered to the rear surface DD-LP of the display device DD. An adhesive strength between the lower surface of the first hole film HFL1 and the rear surface DD-LP of the display device DD may be 0 gf/in. The lower surface of the first hole film HFL1 may be defined as a surface facing the rear surface of the display device DD, and an upper surface of the first hole film HFL1 may be defined as a surface opposed to the lower surface thereof.

For example, the thickness of the first hole film HFL1 in the third direction DR3 may be the same as a sum of the thickness of the first protective film LY1 and the thickness of the second protective film LY2. The height of the upper surface of the first hole film HFL1 may be the same as the height of an upper surface of the second protective film LY2.

The second hole film HFL2 may be on the upper surface of the first hole film HFL1. When viewed in the second direction DR2, one side of both sides (e.g., two opposing sides), of the second hole film HFL2, opposed to each other in the first direction DR1 may be on the upper surface of the second protective film LY2. The one side of both sides, of the second hole film HFL2, opposed to each other in the first direction DR1 may be defined as a side opposed to the other side adjacent to the border of the display device DD.

For example, the thickness of the first hole film HFL1 in the third direction DR3 may be greater than the thickness of the second hole film HFL2 in the third direction DR3. However, the thickness of the first hole film HFL1 and the thickness of the second hole film HFL2 may not be limited thereto.

The second hole film HFL2 may include a first portion PT1 and a second portion PT2. The first portion PT1 may be on the upper surface of the first hole film HFL1. When viewed on a plane, the area of the first portion PT1 may be greater than the area of the first hole film HFL1. The border of the first portion PT1 facing the protective film CTF may protrude further outward than the border of the first hole film HFL1.

The border of the first portion PT1 facing the protective film CTF may be on the upper surface of the second protective film LY2 exposed to the outside from the third protective film LY3. The border of the third protective film LY3 may overlap the border of the second protective film LY2.

In embodiments, an adhesive agent may be between the upper surface of the second protective film LY2 and a lower surface of the first portion PT1. The second protective film LY2 and the first portion PT1 may be adhered to each other via the adhesive agent. For example, an adhesive strength of the adhesive agent may be about 10 gf/in to about 20 gf/in.

The first hole film HFL1 may be fixed on the rear surface DD-LP of the display device DD by the second hole film HFL2 adhered to the protective film CTF. In embodiments, the first hole film HFL1 may cover the first hole H1 and the second hole H2 regardless of a surface roughness of the rear surface DD-LP of the display device DD.

Referring to FIGS. 11A-11B, during the inspection of the first hole region HA1 and the second hole region HA2 of the display device DD, the hole film HFL may be detached from the display device DD. In this case, when an adhesive agent is between the lower surface of the first hole film HFL1 and the rear surface DD-LP of the display device DD, the first hole film HFL1 may not be easily detached according to a material of the rear surface DD-LP of the display device DD. In the case in which the first hole film HFL1 is not easily detached, the rear surface DD-LP of the display device DD may be damaged when the first hole film HFL1 is detached. For example, a phenomenon that the rear surface DD-LP of the display device DD is lifted may occur.

However, in the case of the release film RF according to an embodiment of the present disclosure, the lower surface of the first hole film HFL1 may not be adhered to the rear surface DD-LP of the display device DD. An adhesive strength between the lower surface of the first hole film HFL1 and the rear surface DD-LP of the display device DD may be 0 gf/in. Accordingly, the hole film HFL may be easily detached from the display device DD. Therefore, it is possible to prevent or reduce damage to the rear surface DD-LP of the display device DD.

Referring to FIG. 9, FIG. 10B, and FIG. 11B, the second portion PT2 may extend from the first portion PT1 in the first direction DR1. The second portion PT2 may extend further outward than the border of the display device DD from the first portion PT1. In embodiments, when the hole film HFL is detached from the display device DD, the second portion PT2 may be easily gripped.

For example, when viewed on a plane, the area of the second portion PT2 may be smaller than the area of the first portion PT1.

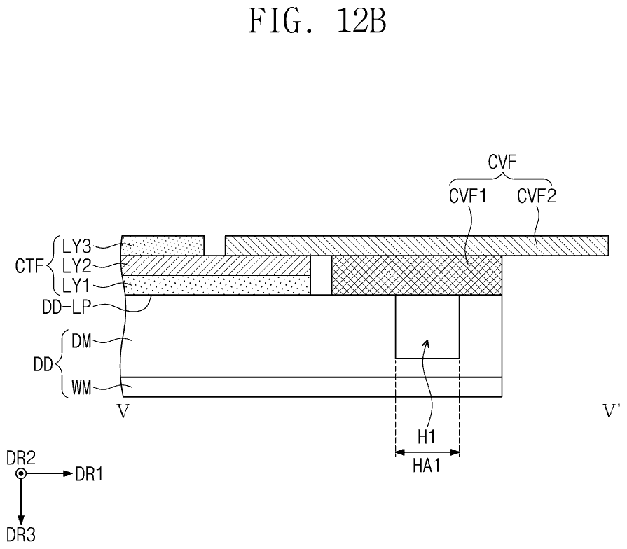

FIGS. 12A-12B are views for illustrating a release film according to an embodiment of the present disclosure.

For example, FIG. 12A is a plan view illustrating a rear surface of a display device DD, and FIG. 12B is a cross-sectional view taken along line V-V′ illustrated in FIG. 12A.

For example, FIG. 12A is a plan view illustrating a state in which the bending region BA (see FIG. 7) of the display panel DP (see FIG. 7) is bent and a second region AA2 is on a rear surface DD-LP of the display device DD.

For example, in FIG. 12A, a first hole H1, a second hole H2, a second region AA2, a printed circuit board PCB, and a data driver DDV are shown as dotted lines.

For example, in FIG. 12B, a display module DM and a window module WM each are briefly illustrated as a single layer.

The display device DD and a protective film CTF of FIGS. 12A-12B are identical or similar to the display device DD and the protective film CTF of FIGS. 8A-8B, and thus description thereof may not be repeated here or may be abbreviated.

Referring to FIG. 11B, FIG. 12A and FIG. 12B, as illustrated in FIG. 11B, a hole film HFL may be removed for the inspection of a first hole region HA1 and a second hole region HA2. After the inspection of the first hole region HA1 and the second hole region HA2 is completed, a cover film CVF may be on the rear surface of the display device DD.

The structure of the cover film CVF may be substantially the same as the structure of the hole film HFL. In embodiments, the cover film CVF may include a first cover film CVF1 and a second cover film CVF2. The first cover film CVF1 may be on the rear surface DD-LP of the display device DD. The first cover film CVF1 may overlap the first hole H1 and the second hole H2. The first cover film CVF1 may cover the first hole H1 and the second hole H2, and thus block or reduce introduction of foreign materials into the first hole H1 and the second hole H2.

A lower surface of the first cover film CVF1 may not be adhered to the rear surface DD-LP of the display device DD. An adhesive strength between the lower surface of the first cover film CVF1 and the rear surface DD-LP of the display device DD may be 0 gf/in.

In embodiments, when the display device DD is conveyed and then accommodated in the case EDC of FIG. 3, the first cover film CVF1 may be detached from the display device DD. The lower surface of the first cover film CVF1 is not adhered to the rear surface DD-LP of the display device DD, and thus the first cover film CVF1 may be easily detached. Therefore, the first cover film CVF1 may be removed without (or substantially without) a damage of the display device DD.

The thickness of the first cover film CVF1 in the third direction DR3 may be the same as a sum of the thickness of the first protective film LY1 and the thickness of the second protective film LY2.

The second cover film CVF2 may be on an upper surface of the first cover film CVF1. The border of the second cover film CVF2 may overlap the border of the first cover film CVF1. The border of the second cover film CVF2 may be on an upper surface of the second protective film LY2. An adhesive strength between a lower surface of the second cover film CVF2 and the upper surface of the second protective film LY2 may be about 10 gf/in to about 20 gf/in.

The first cover film CVF1 may be fixed on the rear surface DD-LP of the display device DD by the second cover film CVF2 adhered to the protective film CTF. In embodiments, the first cover film CVF1 may cover the first hole H1 and the second hole H2 regardless of a surface roughness of the rear surface DD-LP of the display device DD.

When viewed on a plane, a portion of the second cover film CVF2 may extend further outward than a border of the display device DD. Therefore, when detached from the display device DD, the cover film CVF may be easily gripped.

According to an embodiment of the present disclosure, a protective film may be on a rear surface of a display device and in a periphery of a first hole defined in the display device. On the rear surface of the display device, a hole film may overlap the first hole. The adhesive strength between a lower surface of the hole film and the rear surface of the display device may be smaller than the adhesive strength between the lower surface of the hole film and an upper surface of the protective film. The adhesive strength between the lower surface of the hole film and the rear surface of the display device may be 0 gf/inch. Accordingly, the hole film may be easily detachable from the display device. Therefore, when the release film is detached from the display device, damage to the display device may be prevented or reduced.

According to an embodiment of the present disclosure, a first hole film may be fixed on the rear surface of the display device by a second hole film adhered to the protective film. Therefore, the first hole film may cover a first hole region and a second hole region defined in the display device, regardless of a surface roughness of the rear surface of the display device DD. In the above, description has been made with reference to example embodiments of the present disclosure, but those skilled in the art or those of ordinary skill in the relevant technical field may understand that various suitable modifications and changes may be made to the subject matter of the present disclosure without departing from the spirit and the technical scope of the present disclosure as described in the appended claims, and equivalents thereof. In addition, the embodiments disclosed in the present disclosure are not intended to limit the technical spirit of the present disclosure, and all technical ideas within the scope of the appended claims and their equivalents should be construed as being included in the scope of the present disclosure.

What is claimed is:

1. A release film comprising:
a protective film on a rear surface of a display device and in a periphery of a first hole defined in the display device; and
a hole film adjacent to the protective film on the rear surface of the display device, and overlapping the first hole,
wherein the hole film comprises:
a first hole film on the rear surface of the display device, and
a second hole film comprising a first portion on an upper surface of the protective film and an upper surface of the first hole film, and
an adhesive strength between the rear surface of the display device and a lower surface of the first hole film is smaller than an adhesive strength between a lower surface of the first portion and the upper surface of the protective film.

2. The release film of claim 1, wherein an adhesive strength between a lower surface of the first hole film and the rear surface of the display device is 0 gf/in.

3. The release film of claim 2, wherein an adhesive strength between the lower surface of the first portion and the upper surface of the protective film is about 10 gf/in to about 20 gf/in.

4. The release film of claim 1, wherein when viewed on a plane, an area of the first portion is greater than an area of the first hole film.

5. The release film of claim 4, wherein the second hole film further comprises a second portion extending from the first portion and protruding further outward than a border of the display device.

6. The release film of claim 4, wherein the protective film comprises a first protective film, a second protective film, and a third protective film which are sequentially stacked from a lower part to an upper part.

7. The release film of claim 6, wherein when viewed on a plane, an area of the second protective film is greater than an area of the third protective film, and a portion of the second protective film is exposed from the third protective film.

8. The release film of claim 7, wherein the lower surface of the first portion is on an upper surface of a portion of the second protective film exposed from the third protective film.

9. The release film of claim 7, wherein a sum of a thickness of the first protective film and a thickness of the second protective film is the same as a thickness of the first hole film.

10. The release film of claim 9, wherein a thickness of the first hole film is greater than a thickness of the second hole film.

11. A release film comprising:
a protective film on a rear surface of a display device and in a periphery of a first hole defined in the display device; and
a hole film adjacent to the protective film on the rear surface of the display device, and overlapping the first hole,
wherein the hole film comprises a first hole film on the rear surface of the display device and a second hole film adhered to the first hole film,
an adhesive strength between the rear surface of the display device and a lower surface of the first hole film is 0 gf/in, and
a border of the second hole film protrudes further outward than a border of the first hole film and adheres to an upper surface of the protective film.

12. The release film of claim 11, wherein an adhesive strength between the upper surface of the protective film and the lower surface of the second hole film is about 10 gf/in to about 20 gf/in.

13. The release film of claim 12, wherein the second hole film comprises:
a first portion on an upper surface of the first hole film and an upper surface of the protective film; and
a second portion extending, from the first portion, further outward than a border of the display device.

14. The release film of claim 13, wherein the protective film comprises a first protective film, a second protective film, and a third protective film which are sequentially stacked from a lower part to an upper part, and
when viewed on a plane, a border of the second protective film is protrudes further outward than a border of the third protective film.

15. The release film of claim 14, wherein a border of the first portion is on an upper surface of the second protective film.

16. The release film of claim 14, wherein a sum of a thickness of the first protective film and a thickness of the second protective film is the same as a thickness of the first hole film.

17. The release film of claim 16, wherein a height of an upper surface of the first hole film is the same as a height of an upper surface of the second protective film.

18. The release film of claim 14, wherein an adhesive strength between a rear surface of the display device and a lower surface of the first protective film is about 10 gf/in to about 20 gf/in.

19. The release film of claim 13, wherein when viewed on a plane, an area of the first portion is greater than an area of the first hole film.

20. The release film of claim 13, wherein when viewed on a plane, a shape of the first portion corresponds to a shape of the protective film facing the first portion.
